(19) United States
(12) Patent Application Publication
(10) Pub. No.: US 2003/0231736 A1
(43) Pub. Date: Dec. 18, 2003

(54) Counter circuit

(76) Inventor: Mitsuhiro Yamamura, Suwa-shi (JP)

Correspondence Address: HARNESS, DICKEY & PIERCE, P.L.C., P.O. BOX 828, BLOOMFIELD HILLS, MI, 48303, US

(21) Appl. No.: 10/395,873

(22) Filed: Mar. 24, 2003

(30) Foreign Application Priority Data
Mar. 25, 2002 (JP) 2002-084350

(51) Int. Cl. H03K 23/00

(52) U.S. Cl. 377/118

(57) ABSTRACT

High speed multiple-bit binary counter circuits are provided. The multiple-bit counter circuit includes serially connected 1-bit counter circuits 1, wherein the 1-bit counter circuits 1 are divided into at least one lower 1-bit counter circuit for outputting a lower bit and a plurality of upper 1-bit counter circuits for outputting upper bits. Output signals of the upper 1-bit counter circuits are output through latch circuits, and a signal CLK2, which is generated by using a signal generation circuit that receives as an input a last stage output signal of the lower 1-bit counter circuits, is provided as an input signal to the initial stage of the upper 1-bit counter circuits. The latch circuits are timing-controlled by the signal CLK2.

### BACKGROUND OF THE INVENTION

1. Technical Field

The present invention relates to counter circuits, and more particularly, to binary bit counter circuits with multiple bits, and to increasing the speed of a counter circuit of the type that generates a plurality of output signals.

2. Conventional Technology

Conventionally, a multiple-bit binary counter circuit is composed of serially connected 1-bit counter circuits, as indicated in FIG. 3. FIG. 3 shows 1-bit counter circuits 1, an input signal CLK, and output signal wirings CT₁, CT₂, . . . CTₙ₋₁ and CTₙ of the first stage, second stage, . . . n−1^{st} stage and n^{th} stage 1-bit counter circuits.

Operations of the circuit shown in FIG. 3 are described with reference to FIG. 4 that shows operation waveforms of internal signals of the circuit shown in FIG. 3. It is noted that signals CLK, CT₁, CT₂, . . . CTₙ₋₁ and CTₙ in FIG. 4 represent waveforms on the signal wirings that are assigned the same nomenclatures indicated in FIG. 3, respectively.

Referring to FIG. 4, the input signal CLK of the counter circuit is a clock signal, which alternately repeats “0” and “1”. The input signal of the counter circuit does not need to have a constant repeating cycle, but for the sake of easy understanding of the descriptions, it is presented as a waveform of a constant repeating cycle. Further, to make the descriptions readily understandable, initial values of all of the 1-bit counter circuits are set at “0”.

The 1-bit counter circuit of this conventional example inverts an output signal in response to the falls of an input signal. Therefore, the output signal CT₁ of the 1^{st} stage 1-bit counter circuit changes its initial value “0” to “1” in response to a fall of the input signal CLK. Similarly, the output signal CT₂ of the 2^{nd} stage 1-bit counter circuit changes its initial value “0” to “1” in response to a fall of the signal CT₁, and the output signal CTₙ of the n^{th} stage 1-bit counter circuit changes its initial value “0” to “1” in response to a fall of the output signal CTₙ₋₁ from the preceding stage.

If outputs of the 1-bit counter circuits from the 1^{st} stage to n^{th} stage are deemed to be binary data of multiple bits with CT₁ being at the lowest bit and CTₙ being at the highest bit, the data has values ranging from 0 to 2ⁿ−1, which is a result of counting how many cycles the input signal CLK is input, as indicated in FIG. 4.

In the above description, the 1-bit counter circuits each have a function to invert an output signal in response to the falls of an input signal, and thus function as an adder-type counter circuit as a whole. However, if the 1-bit counter circuits each have a function to invert an output signal in response to the rises of an input signal, they function as a subtractor-type counter circuit as a whole.

When the input signal CLK of the conventional multiple-bit binary counter circuit is high speed, the operation time of each of the 1-bit counter circuits, which is minute and thus can be ignored in FIG. 4, becomes relatively large and cannot be ignored.

FIG. 5 shows an example in which 1-bit counter circuits in five stages are sequentially operated when the input waveform CLK is made faster than that shown in FIG. 4.

The symbols in FIG. 5 that are the same as those shown in FIG. 4 represent waveforms on the signal wirings having the same nomenclatures. Also, Δt indicates an operation time of each 1-bit counter circuit, and T indicates a cycle of the input signal CLK.

As indicated in FIG. 5, the operation of the 1-bit counter circuits in five stages requires a time of 5·Δt. During this time, an output of the multiple-bit counter circuit is not defined. Therefore, the output of the counter circuit cannot be read during this time. A period in which an output of the counter circuit is defined, and the output of the counter circuit can be read from the circuit at the succeeding stage is therefore T+Δt−5×Δt=T−4·Δt.

Accordingly, when a conventional multiple-bit binary counter circuit is used, and the number of 1-bit counter circuits that are sequentially operated is a maximum of m stages, the period in which an output of the counter circuit can be read is T−(m−1)Δt.

From the above, it can be understood that, in a conventional multiple-bit binary counter circuit, it becomes more difficult to read outputs of the counter circuit because a difference between the cycle T and a value (m−1) Δt becomes smaller as an input signal speed becomes higher and as the number of 1-bit counter circuits that are sequentially operated increases. In the region where T<(m−1)Δt, an output of the counter circuit is not defined when the m^{th} stage 1-bit counter circuit is sequentially operated. Also, similar incidents occur when Δt becomes larger due to lowered drivability of transistors in high temperature and low voltage regions.

The present invention is directed toward solving the above-described problems of the conventional examples and provides binary counter circuits whose outputs can be normally read at higher speeds with a greater number of bits, and in high temperature and low voltage ranges as compared to the conventional examples.

### SUMMARY

A first counter circuit in accordance with the present invention pertains to a multiple-bit counter circuit comprising: a plurality of serially connected 1-bit counter circuits, wherein at least one of the plurality of 1-bit counter circuits is a lower 1-bit counter circuit for outputting a lower bit, and the remaining 1-bit counter circuits are upper 1-bit counter circuits for outputting upper bits. The output signals of the upper 1-bit counter circuits are output through latch circuits. A control signal generation circuit that receives as an input a last stage output signal of the lower 1-bit counter circuits at the last stage thereof, generates a control signal to control the latch circuits. An input signal generation circuit that receives as an input the last stage output signal of the lower 1-bit counter circuit at the last stage thereof, generates a first stage input signal to the upper 1-bit counter circuits at the first stage thereof.

A second counter circuit in accordance with the present invention is characterized in that, in the first counter circuit of the present invention, the control signal generation circuit generates the control signal that makes the latch circuits have a latch release operation during a specified period starting at a rising or a falling of the last stage output signal of the lower 1-bit counter circuits at the last stage thereof, and the input signal generation circuit generates the first stage input signal that operates the upper 1-bit counter circuits after a latching operation of the latch circuits.

A third counter circuit in accordance with the present invention is characterized in that, in the first or second counter circuit of the present invention, a first reset signal that is commonly input in the plurality of 1-bit counter circuits, an initial value signal that is similarly input in the plurality of 1-bit counter circuits, and a second reset signal that is input in the control signal generation circuit and the first stage input signal generation circuit are further provided.

In accordance with the structures of the present invention, outputs of the binary counter circuit are divided into two sections of upper bit outputs and lower bit outputs. The upper bit outputs among them are output through the latch circuits; during a period in which the latch circuits latch the upper bit outputs, changes in outputs of the upper 1-bit counter circuits are masked. These output changes are reflected in an output of the binary counter circuit at a latch release timing. By this, upper bit outputs appear to simultaneously change at the latch release timing even when the upper bit outputs sequentially change at multiple bits. Therefore, the period in which the upper bit outputs are not defined does not depend on the number of upper bits, and is short.

With the second structure of the present invention, the control signal to the latch circuits causes a latch release operation during a specified period starting at a rise or a fall of a last stage output of the lower bits. Therefore, outputs of the upper 1-bit counter circuits are always reflected in an output of the binary counter once per cycle of last stage outputs of the lower bits.

In the meantime, the input to the initial stage of the upper 1-bit counter circuits operates the upper 1-bit counter circuits after a latch operation, and the latch operation takes place in the same cycle as that of the latch release operation. Accordingly, outputs of the upper 1-bit counter circuits also change in the same cycle as that of the latch release operation. In other words, in the same cycle as that of the outputs of the last stage of the lower bits.

By this, changes in outputs of the upper 1-bit counter circuits are reflected without fail in the outputs of the upper bits of the binary counter.

If, like the conventional circuit, no input signal generation circuit that generates an initial stage input signal to the initial stage of the upper 1-bit counter circuits is provided, an output of the last stage of the lower bits is provided as an initial stage input to the upper 1-bit counter circuits. Therefore, outputs of the upper 1-bit counter circuits likewise change in the same cycle as that of the outputs of the last stage of the lower bits.

The above means that the latch circuits having the structure of the present invention do not inhibit the conventional output capability of a binary counter circuit.

With the third structure of the present invention, the binary counter circuit of the present invention can be set to start a normal operation by resetting the 1-bit counter circuits at an initial value by the first reset signal; and then, prior to a counting operation, causing latch release operations of the latch circuits by the second reset signal, and then operating the 1-bit counter circuits of the upper bits once.

### BRIEF DESCRIPTION OF THE DRAWINGS

FIG. 1 shows a circuit diagram of one example in accordance with a first embodiment of the present invention.

FIG. 2 shows a timing chart of operation waveforms of the circuit shown in FIG. 1.

FIG. 3 shows a block diagram of a conventional multiple-bit binary counter circuit.

FIG. 4 shows a shows a timing chart of operations of the circuit shown in FIG. 3.

FIG. 5 shows a shows a timing chart of operations of the circuit shown in FIG. 3 when operated at a high speed.

FIG. 6 shows a circuit diagram of one example in accordance with a second embodiment of the present invention.

FIG. 7 shows a timing chart of operation waveforms of the circuit shown in FIG. 6.

### DETAILED DESCRIPTION

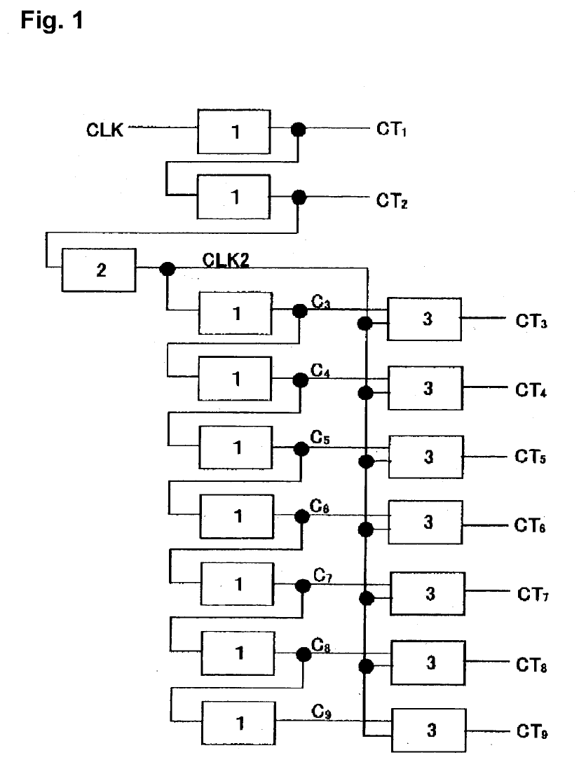

FIG. 1 shows a circuit diagram of one example in accordance with a first embodiment of the present invention.

FIG. 1 includes 1-bit counter circuits 1, an input signal CLK, and output signals CT₁ and CT₂ of the first and second stage 1-bit counter circuits, respectively. Since the counter circuits are serially connected to one another, the output signal CT₁ is also an input signal to the second stage 1-bit counter circuit. Each of the 1-bit counter circuits inverts an output signal at the falls of an input signal.

Also, C3, C4, . . . , C8 and C9 denote output signals of the 3^{rd}, 4^{th}, . . . , 8^{th} and 9^{th} stage 1-bit counter circuits, respectively. Since the counter circuits are serially connected to one another, the output signals C3, C4, . . . , C8 are also input signals to the 4^{th}, 5^{th}, . . . , 9^{th} stage 1-bit counter circuits, respectively.

Each of these 1-bit counter circuits has a function to invert an output signal at the falls of an input signal.

Reference numeral 2 denotes a pulse signal generation circuit that receives the signal CT₂ as an input, and provides a pulse signal CLK2 as an output. The pulse signal CLK2 is an input signal to the 3^{rd} stage 1-bit counter circuit.

The pulse signal generation circuit 2 generates an H pulse signal CLK2 having a specified pulse width that starts at a fall of the input signal CT₂.

Reference numeral 3 denotes latch circuits that receive signals C₃, C₄, . . . , C₈ and C₉ as their inputs, and provide signals CT₃, CT₄, . . . , CT₈ and CT₉ as their outputs, respectively.

Also, the latch circuits 3 are timing-controlled by the H pulse signal CLK2, and transmit the outputs C₃-C₉ of the upper 1-bit counter circuits 1 to the output signals CT₃-CT₉, respectively, only during H pulse periods of the H pulse signal CLK2. During L periods of the H pulse signal CLK2, the latch circuits 3 shut off the signals C₃-C₉ from CT₃-CT₉, and latches the output signals CT₃-CT₉. The output signals CT₃-CT₉ are retained by the latch circuits and do not change during a latch period.

It should be understood from the structure described above that the present embodiment example is a 9-bit binary counter that provides the signals CT₁-CT₉ as outputs. Two (2) bits among these signals, i.e., the signals CT₁ and CT₂, are lower bit outputs, and the remaining seven (7) bits, i.e., the signals CT₃, CT₄, . . . , CT₈ and CT₉ are upper bit outputs.

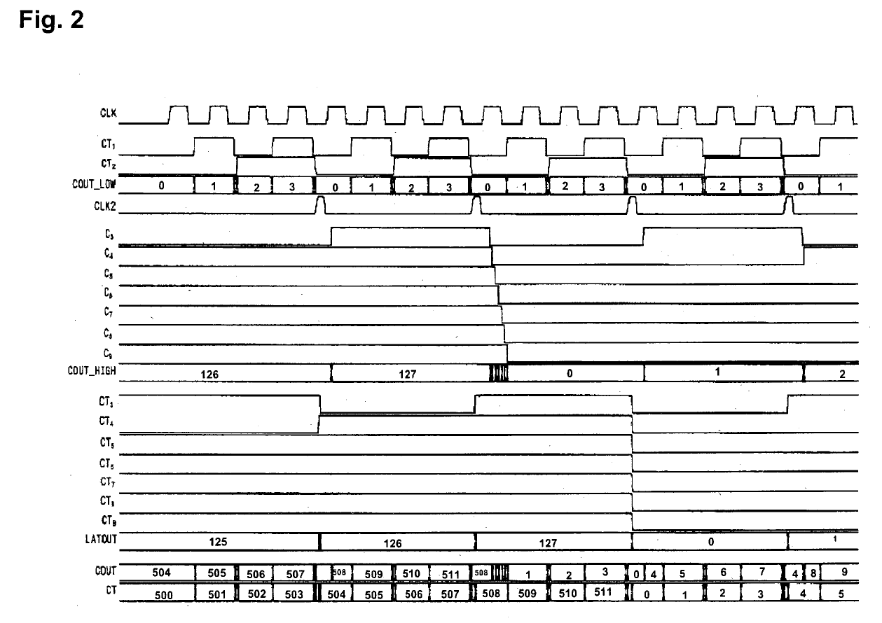

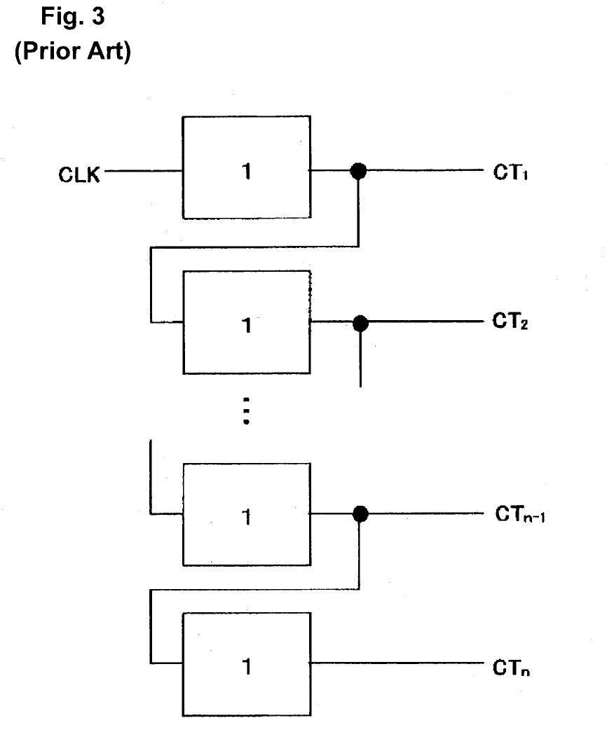

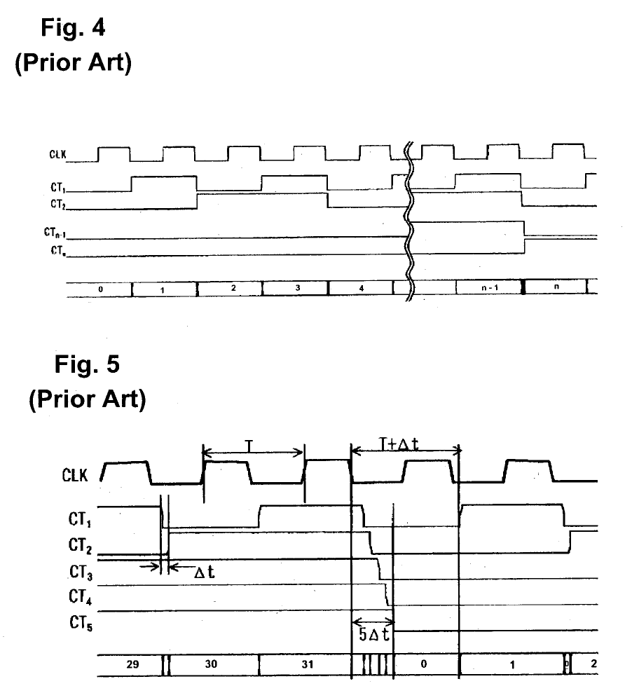

FIG. 2 shows a timing chart of operation waveforms of the circuit shown in FIG. 1.

The symbols in FIG. 2 that indicate the respective waveforms correspond to the signals represented by the same symbols in FIG. 1.

Also, in FIG. 2, the outputs of the entire 1-bit counter circuits 1 are deemed to be 9-bit binary data with CT₉ being the most significant bit and CT₁ being the least significant bit, and COUT indicates values decimally representing the binary data. COUT assumes values ranging from “0” to “511”.

In the meantime, upper bits and lower bits of COUT are independently represented as COUT_HIGH and COUT_LOW, respectively. Among them, the upper bits C₉-C₃ are deemed to be 7-bit binary data, and COUT_HIGH indicates values decimally representing the binary data; and the lower bits CT₂ and CT₁ are deemed to be 2-bit binary data, and COUT_LOW indicates values decimally representing the binary data. Also, because the lower bits are 2 bits, COUT can be calculated as COUT=COUT_HIGH×2²+COUT_LOW.

CT represents output data values of the binary counter circuit of the present embodiment example, which are 9-bit data that are decimally represented by values ranging from “0” to “511”, like COUT.

The upper bits CT₉-CT₃ among CT are output data of the latch circuits 3, which are expressed as independent 7-bit binary data LATOUT, like COUT_HIGH in FIG. 2. In the meantime, the lower bits of CT are equal to COUT_LOW. CT can also be calculated as CT LATOUT×2²+COUT_LOW, similarly to COUT.

It is noted that the circuit in FIG. 1 is not equipped with a circuit that initializes the 1-bit counter circuits 1 and the latch circuits 3, such that last values in the preceding operation are retained as output values of the respective circuits. In FIG. 2, the circuits are operated in a manner that the output values COUT_HIGH and COUT_LOW of the respective upper and lower 1-bit counter circuits are given “126” and “0” as initial values, respectively, and the output value LATOUT of the latch circuits are given “125” as an initial value. The output value COUT of the entire 1-bit counter circuits and the output data CT of the binary counter circuit are “504” and “500” that are calculated based on these values, respectively.

Operations of the circuit of FIG. 1 are described below with reference to FIG. 2.

Each of the 1-bit counter circuits 1 inverts an output signal at the falls of an input signal. Therefore, in FIG. 2, when the input signal CLK changes in one cycle and falls, the output signal CT₁ changes from “0” to “1”. By this, the lower bit output value COUT_LOW changes from “0” to “1”. The upper bit 1-bit counter circuits maintain the output value COUT_HIGH at the initial value of “126” since there is no change in their input signals. By this, COUT changes from “504” to “505”.

The latch circuit output LATOUT is also maintained at the initial value of “125” since there is no change in the input signal CLK2. However, the output data CT of the binary counter circuit changes from “500” to “501” due to the change in the lower bit output values COUT_LOW.

Next, when the input signal CLK changes in another cycle and falls, the output signal CT₁ changes from “1” to “0”. Further, the second stage 1-bit counter circuit also changes its output signal CT₂ from “0” to “1” due to the fall of its input signal CT₁. By this, the lower bit output value COUT_LOW goes through a slight undefined period and then changes from “1” to “2”. Similar to the above, since the output value COUT_HIGH of the upper bit 1-bit counter circuits 1 and the latch circuit output LATOUT are maintained at “126” and “125”, respectively, COUT changes from “505” to “506”, and CT changes from “501” to “502”.

In this manner, when operations of the lower bits do not transmit to the upper bits, COUT and CT provide adder-type counter outputs that count cycles of the input signal CLK at the same timing.

On the other hand, when operations of the lower bits transmit to the upper bits, COUT and CT operate at different timings.

In FIG. 2, at the time when COUT_LOW changes from “3” to “0”, and the last stage output signal CT₂ of the lower 1-bit counter circuits 1 falls, the pulse signal generation circuit 2 generates an H pulse on the signal CLK2.

As the CLK2 changes to H, the value of COUT_HIGH is first transmitted to LATOUT. Then, when the CLK2 changes to L, the value LATOUT is shut off from the value COUT_HIGH and maintained, and COUT_HIGH is counted up as a result of the fall of the CLK2.

Through the above, COUT_HIGH always has a value that is equal to the value LATOUT plus 1.

At this time, the time from the completion of count-up operation of the upper bit 1-bit counter circuits 1 until the value COUT_HIGH is defined extends in proportion to the number of 1-bit counter circuits 1 that change their outputs. For example, in FIG. 2, when COUT_HIGH changes from “127” to “0”, all of the upper 1-bit counter circuits 1 at the seven stages change their outputs, and therefore the time until COUT_HIGH is defined becomes the longest.

According to the timings indicated in FIG. 2, the input signal CLK enters the next cycle during the above time period, and COUT_LOW changes from “0” to “1”. With this timing, the output of the 1-bit counter circuits COUT reaches a timing to change to “1” while it is about to change from “511” to “0”. Consequently, COUT does not change to be “0” when it is supposed to change to be “0”.

In the meantime, during a period when COUT_HIGH is taking time to change, the value LATOUT is in a state that latches the value COUT_HIGH before the change, and therefore the undefined state of COUT_HIGH does not affect LATOUT at all. After COUT_HIGH is defined, the bits of LATOUT simultaneously change by CLK 2. Therefore, the period in which LATOUT changes does not depend on the number of changing bits, and becomes short.

For example, when LATOUT changes from “127” to “0”, all of the bits of LATOUT change, but the time until LATOUT is defined is extremely short just as it changes from a different value to another value. Therefore, even with the timings indicated in FIG. 2, the input signal CLK does not enter the next cycle during the time in which LATOUT is not yet defined. By this, the output value CT of the binary counter circuit securely changes from “511” to “0”, unlike the output value COUT of the 1-bit counter circuits.

As described above, by using the fact that the upper bits do not have to change during a period in which the lower bits are counted up, the counter circuit shown in FIG. 1 shuts off counting up of the upper 1-bit counter circuits from external outputs during the period. The counting up period of the upper 1-bit counter circuits itself extends in proportion to the number of sequentially operated bits that are composed of the 1-bit counter circuits. However, by the shut-off operation using the latch circuits described above, the time required for changing all the outputs of the binary counter circuit becomes short, which does not depend on the number of the upper bits.

The operations described above can be expressed by the following calculation formulas:

When the maximum cycle of the input signal CLK is T, the operation time of each 1-bit counter circuit 1 is Δt, the pulse width of the H pulse signal CLK2 is t1, the time required for a transmitting operation from COUT_HIGH to LATOUT is t2, the number of lower bits is n, and the number of upper bits is m, the circuit shown in FIG. 1 has a normal operation if the pulse width t1 of the CLK2 and a period m Δt during which all of the upper bits operate are within the cycle 2ⁿ T of CLK2. Therefore, the first operational condition is as follows:

t1+mΔt≦2ⁿT (1-1)

Next, because the transmitting operation from COUT_HIGH to LATOUT needs to be completed while the H pulse signal CLK2 is at the H level, the second operational condition is as follows:

t2<t1 (1-2)

Then, an output of the binary counter can be read during a time period that is equal to a time period of T+Δt starting from a fall of the input signal CLK until the least significant 1-bit counter circuit 1 operates in response to the next fall of the input signal CLK minus a time period of n Δt+t2 during which the binary counter output CT is undefined, which is:

T−(n−1)n Δt−t2 (2)

This is a sufficiently long time against a time period during which the conventional circuit can read under any of the circumstances such as high speed inputs that reduce T, multiple bits that increase m, and high temperatures or low voltages that increase Δt, which is:

T−(m+n−1)Δt (3)

For example, for some reasons such as high speed inputs, multiple bits, higher temperatures or lower voltages, let us assume that counter outputs of a conventional 9-bit binary counter circuit cannot be read out at all when all of the 1-bit counter circuits are sequentially operated. In this instance, the period during which outputs of the conventional binary counter circuit can be read is as follows:

T−(9−1)Δt, (3′)

which is 0.

On the other hand, in accordance with the present embodiment example, when formulas that are derived from the aforementioned conditions, i.e., Δt=T/8 and m+n=9, are substituted into Formulas (1-1) and (2), the following formulas are given:

t1≦(2ⁿ⁺³−9+n)T/8 (1′-1)

(9−n)T/8−t2 (2′)

Operational conditions and readable time can be calculated with the above formulas. For example, when n=1, the above formulas give t1≦T and T−t2, respectively; when n=2, they give t1≦25T/8 and 7T/8−t2, respectively; and when n=3, they give t1≦29T/4 and 6T/8−t2, respectively. In any of these cases, if t1 is sufficiently small, it is operational, and if t2 is sufficiently small, outputs of the binary counter circuit can be read out with good margins.

In this manner, the use of the circuit in accordance with the present embodiment example can generate outputs that can be normally read even in circumstances of high speed inputs, multiple bits, high temperatures or low voltages that the conventional circuit could not normally read.

It is noted that the present embodiment example uses an adder-type counter circuit as an individual 1-bit counter circuit, which inverts an output signal at the falls of an input signal, and the H pulse signal CLK 2. However, arrangements can be readily made such that a subtractor-type counter circuit that inverts an output signal at the rises of an input signal is used as an individual 1-bit counter circuit, and an L pulse signal CLK 2 is used.

Also, in the present embodiment example, the binary counter circuit provides a total of 9 bits composed of 7 upper bits and 2 lower bits. However, these bit numbers can be varied within a range where Formulas (1-1) and (1-2) are satisfied, and the time period under Formula (2) in which output values can be normally read is secured.

In the present embodiment example, the input signal to the 3^{rd} stage 1-bit counter circuit and the timing control signal for the latch circuits 3 are the pulse signal CLK 2 that is equally generated by the pulse signal generation circuit 2.

It is understood from Formulas (1-1) and (2) that, the smaller the pulse width t1 of the input signal to the 3^{rd} stage 1-bit counter circuit, the greater the number of upper bits m, the smaller the number of lower bits n, and the wider the readable time can be made. On the other hand, the pulse width t1 of the timing control signal to the latch circuits 3 needs to be made longer than t2, as understood from Formula (1-2). Furthermore, the capability of the pulse signal generation circuit 2 to drive the pulse signal CLK2 can be low without any problem in operating the 3^{rd} stage 1-bit counter circuit alone, but the capability of the pulse signal generation circuit 2 to drive the pulse signal CLK2 needs to be made higher to operate the seven latch circuits 3.

In view of the above, an input signal to the 3^{rd} stage 1-bit counter circuit and a timing control signal to the latch circuits 3 may be generated by independent pulse signal generation circuits 2. Further, if the cycle of the pulse signal CLK2 is the same as the cycle of the last stage output of the lower 1-bit counter circuits, pulse signals CLK2 that are input in the plural circuits may not necessarily be made by the common circuit, and the desired effects can be expected even when pulse widths thereof are not the same.

Similarly, in view of the input signal CLK2 to the 3^{rd} 1-bit counter circuit, this signal realizes a function to operate the 3^{rd} and succeeding stages 1-bit counter circuits at a time t1 after a fall of the signal CT₂. Therefore, a signal that is created by delaying the signal CT₂ by a time t1 can realize exactly the same function. Such a delay circuit can be incorporated within the 3^{rd} 1-bit counter circuit. Also, the latch circuits 3 themselves may be provided with a function that shuts off the signals C₃-C₉ from the signals CT₃-CT₉ for a period of t2 starting from a rise or a fall of an input signal, and latches output signals CT₃-CT₉. In this case, the timing control signal CLK2 to the latch circuits 3 can use the signal CT₂ or an inverted signal of CT₂ to achieve desired operations.

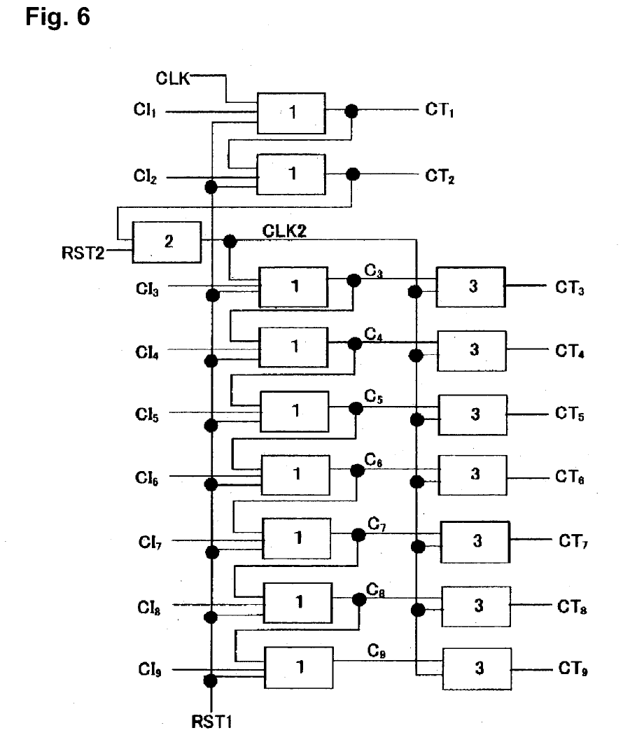

FIG. 6 is a circuit diagram of an example in accordance with a second embodiment of the present invention.

In FIG. 6, the same symbols as those of FIG. 1 indicate the same circuit blocks and signals shown in FIG. 1. Further, in FIG. 6, RST1 indicates a reset signal that is commonly connected to 1-bit counter circuits, CI₁-CI₉ indicate initial value signals that are connected to the 1^{st}-9^{th} stage 1-bit counter circuits, respectively, and RST2 indicates a reset signal that is connected to a pulse signal generation circuit 2 and generates H pulse signals on a signal CLK2.

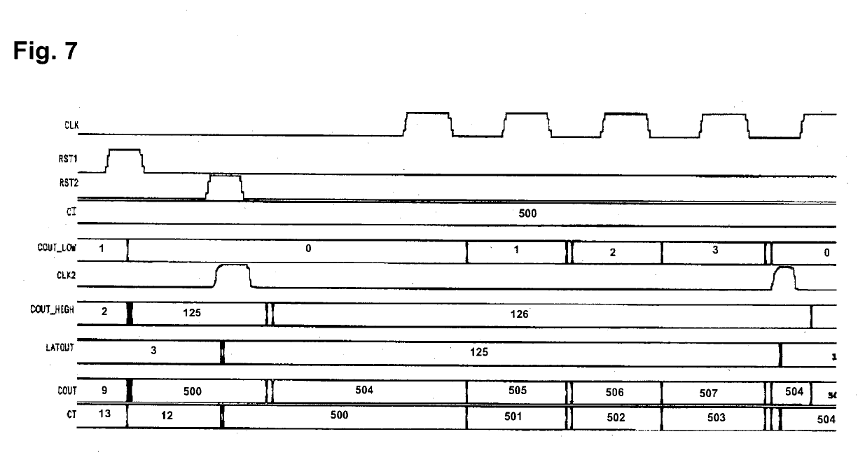

FIG. 7 shows a timing chart of operation waveforms of the circuit shown in FIG. 6.

Symbols indicating the respective waveforms in FIG. 7 are identical with the symbols in FIG. 6 that indicate the corresponding signals.

Also, CI₉-CI₁ are deemed to be 9-bit binary data, and CI in FIG. 7 indicates a value that decimally represents the binary data.

The circuit in FIG. 6 has exactly the same counting operation as that of the circuit shown in FIG. 1. However, it is different from the circuit shown in FIG. 1 in that its initial values can be set. Referring to FIG. 7, these operations are described.

In FIG. 7, the initial value CI is “500”, and the binary counter circuit shown in FIG. 6 is initialized by this value. First, when the reset signal RST1 turns to H, the 1-bit counter circuits 1 are initialized by the signals CI₉-CI₁, respectively, during this period, and provide an output COUT which is “500”.

At this moment, when the signal CT₂ falls, an H pulse is generated on the signal CLK2, and there is a possibility that COUT_HIGH is counted up. Accordingly, the 1-bit counter circuits 1 are set such that they do not count up during the initialization by the signal RST1.

Next, to transfer the value of COUT_HIGH to an output signal LATOUT of the latch circuits, and to count up the value of COUT_HIGH without regard to actions of the signal CT₂, an H pulse signal is input in the reset signal RST2 to generate an H pulse on the signal CLK2.

By this, the binary counter output CT is set at an initial value “500”, and the value of output COUT_HIGH of the upper bit 1-bit counter circuits changes to be “126” that is equal to a value “125” of output signal LATOUT of the latch circuits 3 plus one, such that the counting operation is ready. Succeeding operations are the same as those shown in the timing chart of FIG. 2.

Similar to the circuit shown in the circuit diagram of FIG. 2, the present embodiment example does not have any problems if each 1-bit counter circuit is a subtractor counter circuit, and can be readily arranged to use an L pulse signal CLK 2. Also, in the present embodiment example, the binary counter circuit likewise provides a total of 9 bits composed of 7 upper bits and 2 lower bits. However, the present invention is not particularly restricted to these numbers. Similarly, the pulse signals CLK2 that are to be input in individual circuits may be created by different generation circuits and with different pulse widths. Instead of providing the signal CLK2 with pulse signals, modifications can be made to use a delay signal of CT₂, the signal CT₂ itself, or an inverted signal of CT₂.

Furthermore, the reset signals RST1 and RST2 may be composed of signals other than H pulse signals. Besides setting the 1-bit counter circuits such that they do not count up during the initialization by the signal RST1, the same effects can be obtained by making an arrangement such that the signal CLK2 does not change when the signal RST1 is input.

Also, the initial value signal CI does not need to have the same bit number as that of the binary counter circuit in accordance with the present invention. For example, all the bits in CI may be short circuited to the GND level such that the initial value is always “0”. Alternatively, in one structure, only specified ones of the bits may be initialized.

As described above, the present invention can realize multiple-bit binary counter circuits that can generate outputs that can be normally read even with high speed inputs and multiple bits, and in high temperature and high voltage regions. Also, initial values can be set such that the count operation of the present invention can be started with any optional values.

The entire disclosure of Japanese Patent Application No. 2002-084350 filed Mar. 25, 2002 is incorporated by reference.

What is claimed is:

1. A multiple-bit counter circuit comprising:
a plurality of serially connected 1-bit counter circuits, wherein at least one of the plurality of 1-bit counter circuits is a lower 1-bit counter circuit outputting a lower bit, and the remaining 1-bit counter circuits are upper 1-bit counter circuits outputting upper bits, and output signals of the upper 1-bit counter circuits are output through latch circuits;
a control signal generation circuit receiving an output signal of a last stage of the lower 1-bit counter circuits as an input and generating a control signal controlling the latch circuits; and
an input signal generation circuit receiving the output signal of the last stage of the lower 1-bit counter circuits as an input and generating an input signal for a first stage of the upper 1-bit counter circuits.

2. A multiple-bit counter circuit according to claim 1, wherein:
the control signal generation circuit generates the control signal making the latch circuits perform a latch release operation during a specified period starting from at least one of a rise-time and a fall-time of the output signal of the last stage of the lower 1-bit counter circuits; and
the input signal generation circuit generates the input signal operating the first stage of the upper 1-bit counter circuits after the latch release operation of the latch circuits.

3. A multiple-bit counter circuit according to claim 1, further comprising:
a first resetting signal source commonly inputting a first resetting signal in the plurality of 1-bit counter circuits;
an initial value signal source commonly inputting an initial value signal in the plurality of 1-bit counter circuits; and
a second resetting signal source inputting a second resetting signal in the control signal generation circuit and the input signal generation circuit.
